(19) United States
(12) Patent Application Publication
(10) Pub. No.: US 2015/0187618 A1
(43) Pub. Date: Jul. 2, 2015

(54) SYSTEM AND METHOD FOR FORMING GAN-BASED DEVICE

(71) Applicant: Enkris Semiconductor, Inc., Jiangsu (CN)

(72) Inventor: Kai Cheng, Jiangsu (CN)

(73) Assignee: Enkris Semiconductor, Inc., Jiangsu (CN)

(21) Appl. No.: 14/143,650

(22) Filed: Dec. 30, 2013

(51) Int. Cl. H01L 21/67; C23C 16/458; C23C 16/34; C23C 16/50

(52) U.S. Cl. CPC H01L 21/67201; H01L 21/67167; H01L 21/67207; C23C 16/50; C23C 16/458; C23C 16/34

(57) ABSTRACT

A system and a method for forming a GaN based device are provided. The system may include: at least one MOCVD reaction chamber; at least one ALD or CVD reaction chamber; and a loadlock transfer connecting with the MOCVD reaction chamber and the ALD or CVD reaction chamber. The MOCVD reaction chamber may be a standard chamber for nitride growth. The ALD or CVD reaction chamber may be used for growing nitride and oxide dielectric layers, which may have a highest growth temperature no less than about 500° C., such that nitride and oxide may have better qualities. The system may include a cleaning chamber for cleaning the substrate and the nitride films. Using the integrated system, cleaning processes and growing processes for epitaxial layers and dielectric layers can be implemented in a same system, which may avoid contaminations in the air. Device performance may be improved.

### FIELD OF THE DISCLOSURE

The present disclosure generally relates to micro electric technology, and more particularly, to a system and a method for forming a GaN-based device.

### BACKGROUND OF THE DISCLOSURE

GaN is identified as the most important semiconductor material after Si. GaN is a wide band gap material, and its spectrum covers the whole visible light region. GaN can be used to form following optical devices: blue and white light emitting diodes (LEDs) for illustration, TV backlight and general illumination; green and blue LEDs for full color display together with AlGaInP based red LEDs; and ultra-violet (UV) laser diodes for data storage. In addition to its outstanding optical characteristics, GaN also has remarkable electrical properties, such as high electron mobility (about 2000 cm²/VS in 2DEG), high electron saturated drift velocity (about 2.5E7 cm/s), high critical electrical field (about 3.5 MV/cm), and etc. GaN can also be used in RF and power electronics applications.

The critical electrical field of GaN is ten times higher than that of Si. Thus, GaN based power switches may have very low on-state resistance under the same breakdown voltage. Manufacturing costs also play an important role for market acceptance. Compared with GaN based light emitting devices, GaN power switching devices are more sensitive to production cost. That may be partially true because GaN based light emitting devices are almost the only choice for emitting lights with wavelength ranging from about 550 nm to about 200 nm (that is, green light to UV light). In contrast, GaN based power switches need to compete with Si based power device such as MOSFET, CoolMOS, IGBT, and etc. As a result, compared with Si based devices, GaN based devices are required to have better performance, and also competitive costs. For these reasons, it might be more economic to grow GaN material on large size Si substrates, which is the best way to leverage performance and cost.

However, it is very difficult to grow GaN on a Si substrate. Due to the large lattice mismatch and thermal mismatch between Si and GaN, GaN epi-layers grown Si in general show large wafer bow or even cracks without stress engineering. In addition, Ga atoms may act with Si atoms and result in melt back etching effect. The action may be enhanced in the presence of ammonia. Therefore, chamber cleaning and frequent parts replacement are required to prevent Si surfaces from being damaged in a Ga-rich condition.

Therefore, there is a need to provide a system and a method for forming a GaN based device.

### BRIEF SUMMARY OF THE DISCLOSURE

The present disclosure provides a method and a system for forming a GaN based device.

The system is an integrated system which is equipped with at least one ALD or CVD reaction chamber and at least one MOCVD reaction chamber. In the ALD or CVD reaction chamber, Al₂O₃ or AlN thin films may be formed in a Ga-absence environment with thermal decomposition or plasma enhanced decomposition. In some embodiments, the system may include a cleaning chamber which is used to remove intrinsic oxides on the silicon substrate before the Al₂O₃ or AlN thin films are formed.

The silicon substrate, which is cleaned, is transferred to the ALD or CVD reaction chamber by using a vacuum interconnecting system, such that the silicon substrate would not be exposed to air. The quality of the Al₂O₃ or AlN thin films may be improved by using the cleaning chamber. After the Al₂O₃ or AlN thin films are formed in the ALD or CVD reaction chamber, the silicon substrate may be transferred to the MOCVD reaction chamber by the vacuum interconnecting system, such that air contamination may be avoided, which is beneficial for improving film quality. In the MOCVD reaction chamber, nitride epitaxial films can be formed repeatedly on films containing no Ga atoms. Since the silicon substrate is already covered by a condensed Al-containing thin film, erosion caused by Ga atoms to the silicon substrate can be avoided. Therefore, the MOCVD reaction chamber can be repeatedly used without cleaning.

After the epitaxial layer is formed, the silicon substrate with the epitaxial layer may be transferred from the MOCVD chamber to a preparation chamber, or to the ALD or CVD chamber again to have a dielectric film formed thereon. The dielectric layer may function as a passivation layer in a power device or additionally a dielectric layer under a gate in a power device. The nitride layers (including III group nitrides and AlN) formed in the MOCVD reaction chamber and the dielectric layer formed in the ALD or CVD reaction chamber are not exposed to outer environment, the surface state density may be greatly reduced. Such that, the possibility of current collapse may be reduced and device performance may be improved.

According to one embodiment, a system for forming a GaN based device is provided, including:
at least one metal organic chemical vapor deposition (MOCVD) reaction chamber;
at least one atomic layer deposition (ALD) reaction chamber or chemical vapor deposition (CVD) reaction chamber; and
a loadlock transfer connecting with the at least one MOCVD reaction chamber and the at least one ALD or CVD reaction chamber.

Optionally, the system further includes at least one cleaning chamber for cleaning wafers, epitaxial layers or processed active areas.

Optionally, the MOCVD reaction chamber includes a heating device, a vacuum system and a gas transportation system.

Optionally, the ALD or CVD reaction chamber provides O₃ and/or H₂O, and the ALD or CVD reaction chamber further includes a MO source, a Si source and a nitrogen source.

Optionally, the nitrogen source includes N₂ and/or NH₃.

Optionally, each of the MOCVD reaction chamber and the ALD or CVD reaction chamber is equipped with a plasma source.

Optionally, the loadlock transfer includes a loadlock chamber, a transmission mechanism, a delivery tray and a driven mechanism, where the loadlock chamber connects two neighboring reaction chambers and exhausts gas carried from a reaction chamber with a wafer, the delivery tray is used to hold a wafer to be processed, the driven mechanism drives the transmission mechanism to move, and the transmission mechanism carries the delivery tray.

Accordingly, a method for forming a GaN based device is provided according to one embodiment of the present disclosure, including:
providing a plurality of reaction chambers including at least one MOCVD reaction chamber and at least one ALD or CVD reaction chamber; and
using a loadlock transfer to feed a device to be processed to the plurality of reaction chambers for implementing corresponding processes according to a predetermined sequence, where each of the plurality of reaction chambers supplies corresponding gas or liquid or plasma under certain conditions.

Optionally, the method further includes: using plasma, gaseous HF, HCl or H₂ to clean wafers, epitaxial layers or processed active areas.

Optionally, the highest temperature in the ALD or CVD reaction chamber is equal to or higher than about 500° C.

The present disclosure may have following advantages.

In the ALD or CVD reaction chamber, not only oxidations but also nitrides can be formed.

Compared with a conventional ALD reaction chamber, the ALD reaction chamber of the present disclosure may provide higher temperature, which may be higher than 500° C., 800° C. or even 1000° C., such that qualities of AlN and Al₂O₃ thin films may be improved.

When polycrystalline and even monocrystalline oxides are formed on the silicon substrate in the ALD reaction chamber, there is no background contamination of Ga atoms. Therefore, the silicon substrate is well protected and may have better surface quality. The oxides formed in the ALD or CVD reaction chamber may include Al₂O₃, HfO₂, AlHfO₂, ScO₂, SiO₂, SiON and etc.

A cleaning chamber is provided in the integrated system including MOCVD and ALD reaction chambers, such that wafer, epitaxial layers and/or active areas after etch can be cleaned. Qualities of epitaxial layers and dielectric layers may be improved, and current collapse may be suppressed.

After the nitride is formed in the MOCVD reaction chamber, the epi-structure is transferred to the ALD or CVD reaction chamber to implement oxides or SiN deposition. As all the processes are conducted within a same system, cross contaminations and surface oxidation during ex situ transfer may be reduced.

In the MOCVD reaction chamber, the growth speed of SiN may be limited. Thicker SiN films can be formed in the ALD or CVD reaction chamber.

After a very thin SiN film or a SiN cap layer is formed in the MOCVD reaction chamber, the substrate may be transferred to the ALD or CVD reaction chamber to have a SiN passivation layer formed thereon. The SiN passivation layer may have a thickness greater than 100 nm. In such configuration, surface states resulting in current collapse effect may be suppressed.

Further processing may be performed to the gate. GaN may be formed on a dielectric layer, or else, a dielectric layer may be formed on GaN. Since there is no surface contamination, the gate channel may have better performance.

### BRIEF DESCRIPTION OF THE DRAWINGS

Accompanying drawing used in following descriptions will be briefly illustrated hereinafter to provide better understanding of the present disclosure. Apparently, these drawings depict only several embodiments in accordance with the disclosure. Those skilled in the art may obtain other drawings based on these drawings without an innovative step.

FIG. 1 illustrates a schematic block diagram of a system for forming a GaN based device according to one embodiment of the present disclosure.

FIG. 2 illustrates a schematic block diagram of a system for forming a GaN based device according to another embodiment of the present disclosure.

FIG. 3 illustrates a schematic block diagram of a system for forming a GaN based device according to another embodiment of the present disclosure.

FIGS. 4A to 4F schematically illustrate cross-sectional views of intermediate structures formed in a formation process of a first type of GaN based HEMT according to one embodiment of the present disclosure.

FIGS. 5A to 5B schematically illustrate cross-sectional views of intermediate structures formed in a formation process of a second type of GaN based HEMT according to one embodiment of the present disclosure.

FIG. 6 schematically illustrates a cross-sectional view of an intermediate structure formed in a formation process of a third type of GaN based HEMT according to one embodiment of the present disclosure.

FIG. 7 schematically illustrates a cross-sectional view of an intermediate structure formed in a formation process of a fourth type of GaN based HEMT according to one embodiment of the present disclosure.

FIG. 8 schematically illustrates a cross-sectional view of an intermediate structure formed in a formation process of a fifth type of GaN based HEMT according to one embodiment of the present disclosure.

FIGS. 9A and 9B schematically illustrate cross-sectional views of intermediate structures formed in back-end processes of a GaN based HEMT according to one embodiment of the present disclosure.

FIG. 10 schematically illustrates a cross-sectional view of an intermediate structure formed in back-end processes of a GaN based HEMT according to one embodiment of the present disclosure.

### DETAILED DESCRIPTION OF THE DISCLOSURE

Embodiments of the present disclosure provide a system for forming a GaN based device. The system is an integrated system which includes:
at least one metal organic chemical vapor deposition (MOCVD) reaction chamber;
at least one atomic layer deposition (ALD) reaction chamber or chemical vapor deposition (CVD) reaction chamber; and
a loadlock transfer connecting with the at least one MOCVD reaction chamber and the at least one ALD reaction chamber.

Accordingly, embodiments of the present disclosure provide a method for forming a GaN based device, including:
providing a plurality of reaction chambers including at least one MOCVD reaction chamber and at least one ALD reaction chamber;
using a loadlock transfer to feed a device to be processed to the plurality of reaction chambers for implementing corresponding processes according to a predetermined sequence, where each of the plurality of reaction chambers supplies corresponding gas or liquid or plasma under certain conditions.

Embodiments of the present disclosure can improve quality of the formed crystals and dielectric layers, thus improving device performance. Besides, the integrated system provided by embodiments can be used to form new devices.

Embodiments of the disclosure will be interpreted in detail in combination with accompanied drawings. However, the present disclosure is not limited by the disclosed embodiments. Any simple modification, variation and polishing based on the embodiments described herein is within the scope of the present disclosure.

Further, the same reference numbers may be used in different drawings to identify the same or similar elements, which are merely for illustrating and not intending to represent interconnections between different embodiments and/or components.

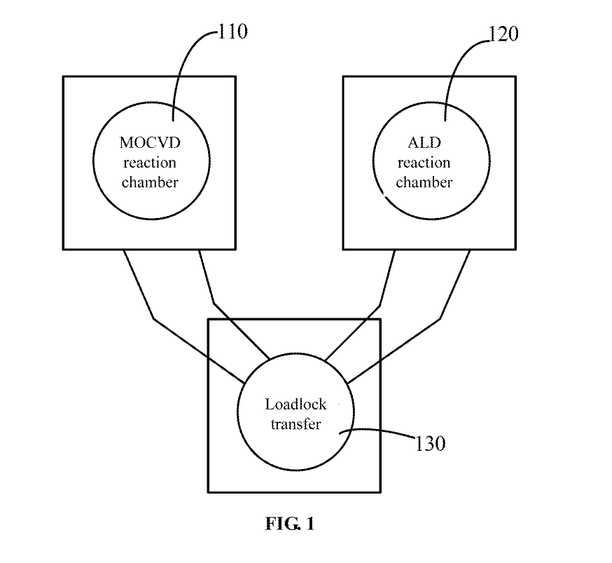

FIG. 1 illustrates a schematic block diagram of a system for forming a GaN based device according to one embodiment of the present disclosure. As shown in FIG. 1, the system includes a MOCVD reaction chamber 110 and an ALD or CVD reaction chamber 120 which are connected through a loadlock transfer 130.

In some embodiments, the MOCVD reaction chamber 110 may include a heating device, a vacuum system and a gas transportation system. In some embodiments, the MOCVD reaction chamber 110 may further include a plasma source.

In some embodiments, the ALD or CVD reaction chamber 120 may provide O₃ and/or H₂O. The ALD or CVD reaction chamber 120 also may have a MO source, Si source and a nitrogen source. In some embodiments, the nitrogen source may include N₂ and/or NH₃ and other gas containing nitrogen. In some embodiments, the ALD or CVD reaction chamber 120 may further be equipped with a plasma source. A relatively high temperature may be required in the ALD or CVD reaction chamber. In some embodiments, the temperature in the ALD or CVD reaction chamber may be equal to or higher than about 500° C. and lower than about 1000° C.

In some embodiments, the loadlock transfer 130 may include a loadlock chamber, a transmission mechanism, a delivery tray and a driven mechanism. The loadlock chamber may connect neighboring reaction chambers, such as a pair of neighboring MOCVD reaction chamber and ALD or CVD reaction chamber. Gas leaked out from a reaction chamber with a wafer may be exhausted in the loadlock chamber. The delivery tray may be used to hold a wafer to be processed. The driven mechanism may drive the transmission mechanism to move. The transmission mechanism may carry the delivery tray, such that the wafer to be processed can move.

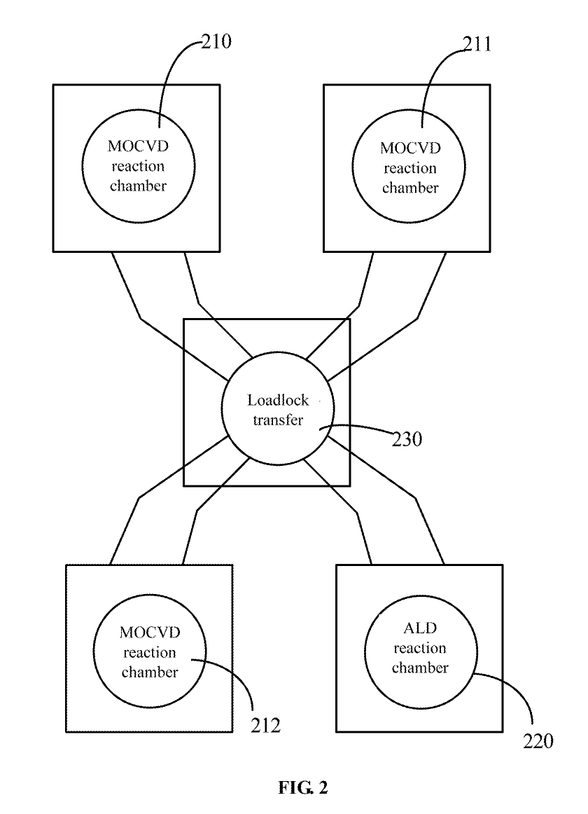

Films formed in ALD or CVD reaction chamber and MOCVD chamber may have distinct growth periods. In some embodiments, one ALD reaction chamber may cooperate with more than one MOCVD reaction chambers, such configuration may improve production efficiency. FIG. 2 illustrates a schematic block diagram of a system for forming a GaN based device according to another embodiment of the present disclosure. As shown in FIG. 2, an ALD or CVD reaction chamber 220 is connected with three MOCVD reaction chambers 210, 211 and 212 through a loadlock transfer 230.

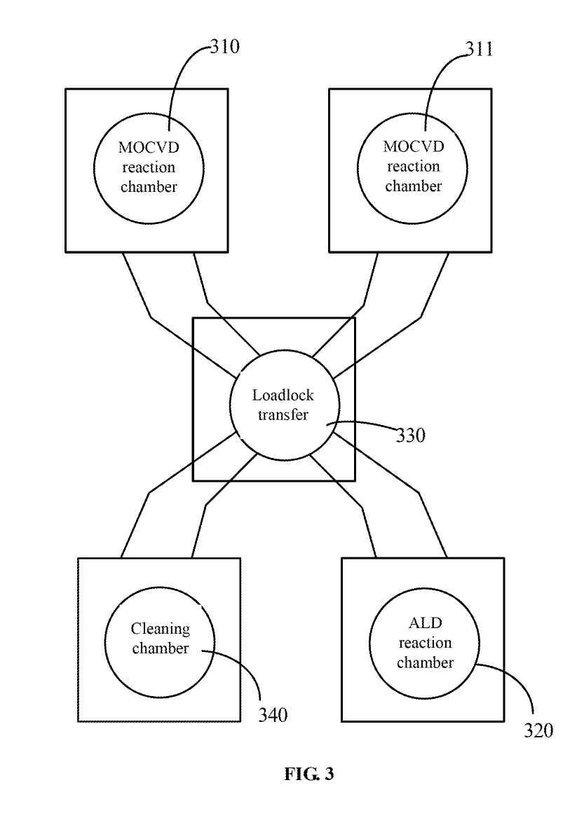

FIG. 3 illustrates a schematic block diagram of a system for forming a GaN based device according to another embodiment of the present disclosure. As shown in FIG. 3, there are two MOCVD reaction chambers 310 and 311 which are connected with an ALD or CVD reaction chamber 320 through a loadlock transfer 330. A cleaning chamber 340 is provided in the system, which is connected with the loadlock transfer 330, such that wafer, epitaxial layers and/or active areas after etch can be cleaned. The cleaning chamber 340 may provide plasma, gaseous HF, HCl or H₂ to clean substances therein. As such, qualities of epitaxial layers and dielectric layers may be improved, and current collapse may be suppressed. In some embodiments, there may be configured with more than one cleaning chambers.

Numbers of the ALD or CVD reaction chamber, the MOCVD reaction chamber and the cleaning chamber illustrated above are merely examples, which are not intending to limit the scope of the present disclosure. In light of the present disclosure, those skilled in the art may vary the specific configurations of the system for forming a GaN based device based on practical requirements.

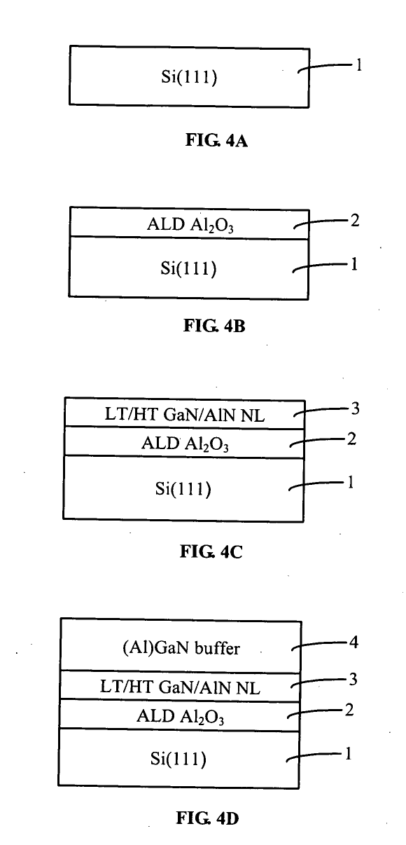

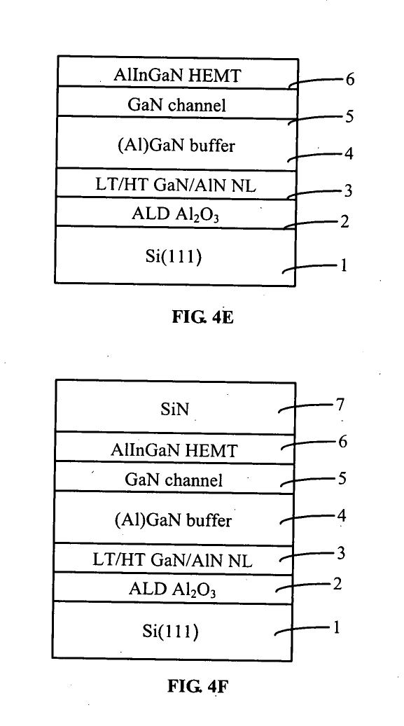

FIGS. 4A to 4F schematically illustrate cross-sectional views of intermediate structures formed in a formation process of a first type of GaN based high electron mobility transistor (HEMT) according to one embodiment of the present disclosure. HEMT structures may be formed by using any of the above described systems integrating ALD and MOCVD reaction chambers. Hereinafter, forming the first type of HEMT by using the system illustrated in FIG. 1 will be described as an example.

Referring to FIG. 4A, a silicon substrate 1 (illustrated as “Si(111)” in figures) is subjected to a cleaning process to remove surface contamination. Thereafter, the silicon substrate 1 is put into the loadlock transfer 130.

Referring to FIG. 4B, the loadlock transfer 130 feeds the silicon substrate 1 into the ALD reaction chamber 120. An Al₂O₃ layer 2 (illustrated as “ALD Al₂O₃” in figures) is formed in the ALD reaction chamber 120. The Al₂O₃ layer 2 may have a thickness ranging from a single atomic layer to several hundreds of nanometers. Normally, the temperature for growing a film in an ALD reaction chamber may range from about 200° C. to about 450° C., such that oxidations formed therein may sustain amorphous to suppress leakage currents in gate structures. However, in some embodiments of the present disclosure, polycrystalline or even monocrystalline oxides are required to be grown on a silicon substrate in ALD processes. Therefore, the ALD reaction chamber in embodiments of the present disclosure may provide a higher temperature for growing oxides, such as higher than 500° C., 600° C., 700° C. or even 800° C. Attributed to absence of background pollutions, surfaces of the silicon substrate may have good qualities in the ALD reaction chamber 120. In some embodiment, the oxides grown in the ALD reaction chamber 120 may be HfO₂, AlHfO₂, ScO₂, SiO₂, SiON or the like. Except for oxide layers, AlN layers may be grown in the ALD reaction chamber 120 to form nucleation layers and protection layers.

Referring to FIG. 4C, the already formed sub-structure illustrated in FIG. 4B is transferred to the MOCVD reaction chamber 110 by the loadlock transfer 130. In the MOCVD reaction chamber 110, a nitride nucleating layer 3 may be formed on the Al₂O₃ layer 2. In some embodiments, the MOCVD reaction chamber 110 may be able to grow films on multiple wafers in one process. Therefore, a plurality of the already formed sub-structures may be temporarily transferred into a storage. When the sub-structures accumulate to a predetermined number, all the stored sub-structures may be transferred to the MOCVD reaction chamber 110 to have nitride grown thereon. To grow GaN or AlN on the sub-structures may be, nucleation layers (NL) are required to grow in advance. The nucleation layers may be low temperature (LT) GaN, low temperature AlN or high temperature (HT) AlN.

Referring to FIG. 4D, on the nitride nucleation layer 3, an AlN or GaN buffer layer 4 (illustrated as “(Al)GaN buffer” in figures) may continue to grow. Thereafter, intercalation technologies may be used to avoid epitaxial fracturing.

Referring to FIG. 4E, after the growing of the buffer layer 4, a GaN channel layer 5 is formed on the buffer layer 4, then an AlInGaN/GaN based HEMT structure 6 (illustrated as “AlInGaN HEMT” in figures) is formed on the GaN channel layer 5.

Referring to FIG. 4F, the already formed sub-structure illustrated in FIG. 4E is transferred to the ALD reaction chamber 120 to have a SiN layer 7 grown thereon, which is for making the AlInGaN/GaN hetero junction more stable. After the nitride is formed in the MOCVD reaction chamber 110, the sub-structure is transferred to the ALD reaction chamber 120 to implement oxide or SiN growth. As all the processes are conducted within a same system, cross contaminations and surface oxidations during transfer may be reduced.

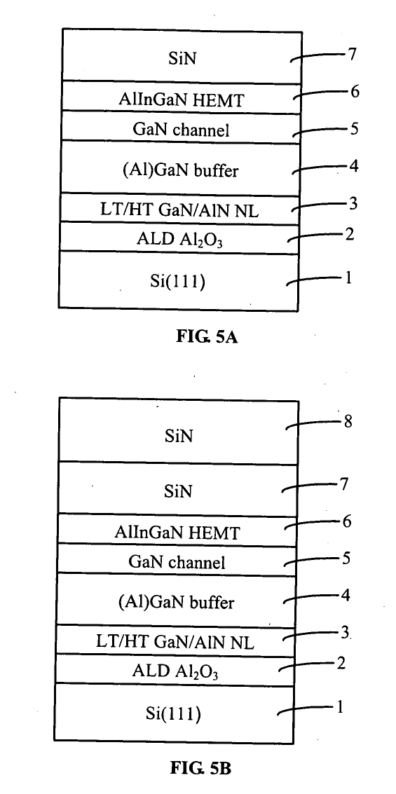

FIGS. 5A to 5B schematically illustrate cross-sectional views of intermediate structures formed in a formation process of a second type of GaN based HEMT according to one embodiment of the present disclosure. Hereinafter, forming the second type of HEMT by using the system illustrated in FIG. 1 will be described as an example.

Growth speed of SiN may be limited due to certain conditions in the MOCVD reaction chamber 110. Therefore, compared with the first type of GaN based HEMT illustrated in FIGS. 4A to 4F, the second type of GaN based HEMT described here may have a very thin SiN passivation layer 7 formed in the MOCVD reaction chamber, as shown in FIG. 5A. The SiN passivation layer 7 may have a thickness less than 50 nm. Thereafter, the substrate with structures formed thereon may be transferred to the ALD or CVD reaction chamber to have a thicker SiN passivation layer 8 grown thereon, as shown in FIG. 5B. The SiN passivation layer 8 may have a thickness greater than 100 nm. In such configuration, surface states resulting in current collapse effect may be suppressed. In some embodiments, the SiN layer(s) may be formed in a high temperature (greater than 500° C.) environment or formed with plasma.

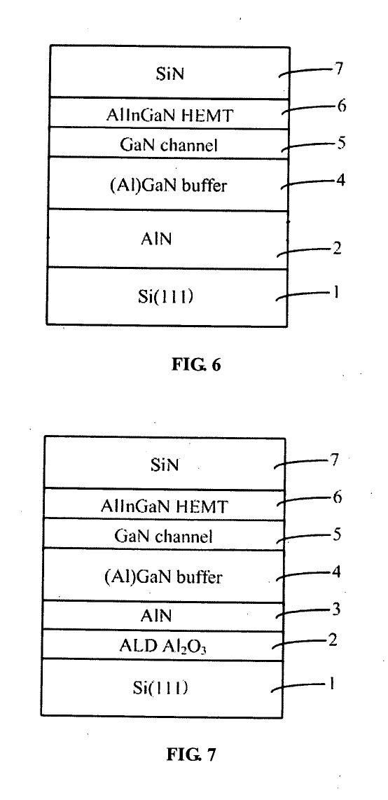

FIG. 6 schematically illustrates a cross-sectional view of an intermediate structure formed in a formation process of a third type of GaN based HEMT according to one embodiment of the present disclosure. Hereinafter, forming the third type of HEMT by using the system illustrated in FIG. 1 will be described as an example. Referring to FIG. 6, compared with the first type of GaN based HEMT, the third type of HEMT doesn't include an Al₂O₃ layer. Optionally, the silicon substrate 1 may be cleaned with a wet etch cleaning system or in-situ cleaned with a cleaning chamber. Thereafter, the after-cleaning silicon substrate is directly transferred to the MOCVD reaction chamber to have a nucleation layer 2 formed thereon. In some embodiments, the nucleation layer 2 is an AlN layer. The SiN passivation layer can be grown in the MOCVD chamber; in the MOCVD chamber and then in the ALD or CVD chamber; in the ALD or CVD chamber.

FIG. 7 schematically illustrates a cross-sectional view of an intermediate structures formed in a formation process of a fourth type of GaN based HEMT according to one embodiment of the present disclosure. Hereinafter, forming the fourth type of HEMT by using the system illustrated in FIG. 1 will be described as an example. Referring to FIG. 7, compared with the third type of GaN based HEMT illustrated in FIG. 6, the fourth GaN based HEMT may have a multi-tier nucleation layer structure. Specifically, the multi-tier nucleation layer structure may include an Al₂O₃ layer 2 formed in the ALD reaction chamber and an AlN layer 3 formed in the MOCVD reaction chamber.

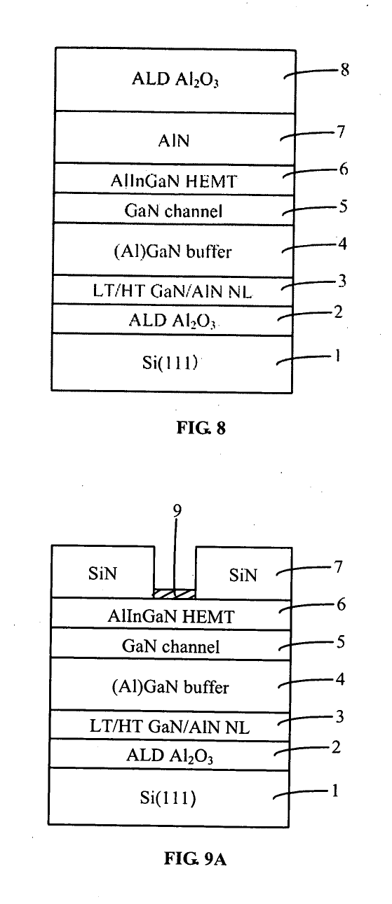

FIG. 8 schematically illustrates a cross-sectional view of an intermediate structures formed in a formation process of a fifth type of GaN based HEMT according to one embodiment of the present disclosure. Hereinafter, forming the fifth type of HEMT by using the system illustrated in FIG. 1 will be described as an example. Referring to FIG. 8, compared with the second type of GaN based HEMT, the fifth GaN based HEMT may have an AlN layer 7 as a surface passivation layer formed in the MOCVD reaction chamber or in the ALD chamber. An Al₂O₃ layer 2 formed in the ALD reaction chamber.

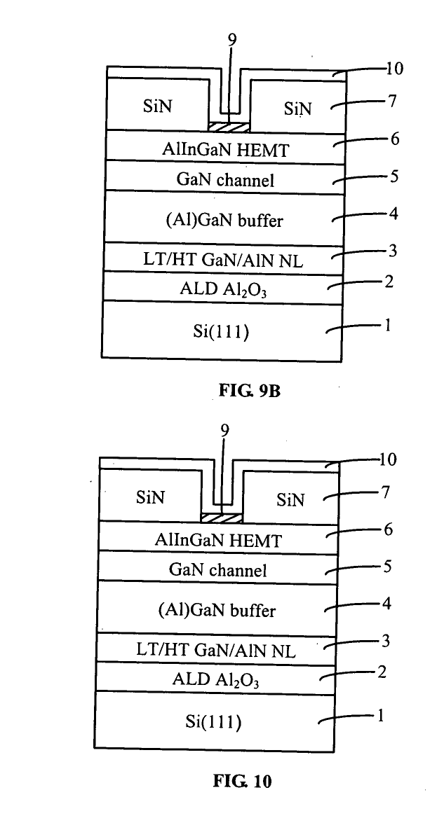

FIGS. 9A and 9B schematically illustrate cross-sectional views of intermediate structures formed in back-end processes of a GaN based HEMT according to one embodiment of the present disclosure.

GaN may be formed on a dielectric layer, or else, a dielectric layer may be formed on GaN. Since there is no surface contamination, the gate channel may have better performance. In the whole epitaxial structure, the SiN layer is the outmost layer, which is used to protect the AlInGaN/GaN hereto junction. The in-situ formed or PECVD/LPCVD formed SiN has an essential functionality, which stabilizes the heretostructure and avoids stress relaxation. Furthermore, the dangling bond density of the AlInGaN layer may be reduced and surface contamination caused by air exposure may be avoided. Therefore, surface states may be suppressed. The SiN passivation layer may also protect the channel. In the gate region, it is required that the gate should not be too far away from the channel, or else the gate may lose control of the channel. Therefore, the SiN layer within the gate region may be partially thinned or completely removed. However, to reduce gate-induced-leakage-current, Schottky contacts in the gate region may be transformed into MIS or MOS structures.

In some embodiments, the gate may be processed by using the integrated system including MOCVD and ALD chambers. As shown in FIG. 9A, the already-formed sub-structure may be etched and then transferred to the MOCVD reaction chamber 110. Cleaning and GaN surface treating processes may be performed with MOCVD to obtain a recovered GaN surface structure 9. As shown in FIG. 9B, after a clean surface is obtained, the sub-structure may be transferred to the ALD or CVD reaction chamber 120 to have an Al₂O₃ or SiN or SiN/Al₂O₃ dielectric layer 10 or other dielectric layers formed thereon.

FIG. 10 schematically illustrates a cross-sectional view of an intermediate structure formed in back-end processes of a GaN based HEMT according to one embodiment of the present disclosure. The already-formed sub-structure may be etched and then transferred to the ALD reaction chamber 120. Oxidation treatment may be performed to the GaN surface structure 9, and then an Al₂O₃ dielectric layer 10 may be formed.

In light of embodiments described above, the present disclosure may have following advantages.

In the ALD or CVD reaction chamber, not only oxides but also nitrides can be formed.

Compared with a conventional ALD reaction chamber, the ALD reaction chamber of the present disclosure may provide higher temperature, which may be higher than 500° C., 800° C. or even 1000° C., such that qualities of AlN and Al₂O₃ thin films may be improved.

When polycrystalline and even monocrystalline oxidations are formed on the silicon substrate in the ALD reaction chamber, there is no background contamination of Ga atoms. Therefore, the silicon substrate may have better surface quality. The oxides formed in the ALD reaction chamber may include Al₂O₃, HfO₂, AlHfO₂, ScO₂, SiO₂, SiON, and the like.

A cleaning chamber is provided in the integrated system including MOCVD and ALD or CVD reaction chambers, such that wafer, epitaxial layers and/or active areas after etch can be cleaned. Qualities of epitaxial layers and dielectric layers may be improved, and current collapse may be suppressed.

After the nitride is formed in the MOCVD reaction chamber, the sub-structure is transferred to the ALD or CVD reaction chamber to implement oxide or SiN growth. As all the processes are conducted within a same system, cross contaminations and surface oxidations during transfer may be reduced.

In the MOCVD reaction chamber, the growth speed of SiN may be limited. Thicker SiN films can be formed in the ALD or CVD reaction chamber.

After a very thin SiN film or a SiN cap layer is formed in the MOCVD reaction chamber, the substrate may be transferred to the ALD or CVD reaction chamber to have a SiN passivation layer formed thereon. The SiN passivation layer may have a thickness greater than 100 nm. In such configuration, surface state introduced current collapse effect may be suppressed.

Further processing may be performed to the gate. GaN may be formed on a dielectric layer, or else, a dielectric layer may be formed on GaN. Since there is no surface contamination, the gate channel may have better performance.

The disclosure is disclosed, but not limited, by preferred embodiments as above. Based on the disclosure of the disclosure, those skilled in the art can make any variation and modification without departing from the scope of the disclosure. Therefore, any simple modification, variation and polishing based on the embodiments described herein is within the scope of the present disclosure.

What is claimed is:

1. A system for forming a GaN based device, comprising:
at least one metal organic chemical vapor deposition (MOCVD) reaction chamber;
at least one atomic layer deposition (ALD) reaction chamber or chemical vapor deposition (CVD) reaction chamber; and
a loadlock transfer connecting with the at least one MOCVD reaction chamber and the at least one ALD or CVD reaction chamber.

2. The system according to claim 1, wherein the system further comprises at least one cleaning chamber for cleaning wafers, epitaxial layers or processed active areas.

3. The system according to claim 1, wherein the MOCVD reaction chamber comprises a heating device, a vacuum system and a gas transportation system.

4. The system according to claim 1, wherein the ALD or CVD reaction chamber provides O₃ or H₂O, and the ALD reaction chamber further comprises a MO source, a Si source and a nitrogen source.

5. The system according to claim 4, wherein the nitrogen source comprises N₂ or NH₃.

6. The system according to claim 1, wherein each of the MOCVD reaction chamber and the ALD or CVD reaction chamber is equipped with a plasma source.

7. The system according to claim 1, wherein the loadlock transfer comprises a loadlock chamber, a transmission mechanism, a delivery tray and a driven mechanism, where the loadloak chamber connects two neighboring reaction chambers and exhausts gas carried from a reaction chamber with a wafer, the delivery tray is used to hold a wafer to be processed, the driven mechanism drives the transmission mechanism to move, and the transmission mechanism carries the delivery tray.

8. The system according to claim 2, wherein the MOCVD reaction chamber comprises a heating device, a vacuum system and a gas transportation system.

9. The system according to claim 2, wherein the ALD or CVD reaction chamber provides O₃ or H₂O, and the ALD or CVD reaction chamber further comprises a MO source, a Si source and a nitrogen source.

10. The system according to claim 2, wherein each of the MOCVD reaction chamber and the ALD or CVD reaction chamber is equipped with a plasma source.

11. The system according to claim 2, wherein the loadlock transfer comprises a loadlock chamber, a transmission mechanism, a delivery tray and a driven mechanism, where the loadloak chamber connects two neighboring reaction chambers and exhausts gas carried from a reaction chamber with a wafer, the delivery tray is used to hold a wafer to be processed, the driven mechanism drives the transmission mechanism to move, and the transmission mechanism carries the delivery tray.

12. A method for forming a GaN based device, comprising:
providing a plurality of reaction chambers comprising at least one MOCVD reaction chamber and at least one ALD or CVD reaction chamber; and
using a loadlock transfer to feed a device to be processed to the plurality of reaction chambers for implementing corresponding processes according to a predetermined sequence, where each of the plurality of reaction chambers supplies corresponding gas or liquid or plasma under certain conditions.

13. The method according to claim 12, further comprising: using plasma, gaseous HF, HCl or H₂ to clean wafers, epitaxial layers or processed active areas.

14. The method according to claim 13, wherein the highest temperature in the ALD or CVD reaction chamber is equal to or higher than about 500° C.
